(19) United States
(12) Patent Application Publication
(10) Pub. No.: US 2013/0276706 A1
(43) Pub. Date: Oct. 24, 2013

(54) DEPOSITION APPARATUS

(71) Applicant: SAMSUNG SDI CO., LTD., Yongin-City (KR)

(72) Inventors: Seung-Hwan Lee, Yongin-City (KR); Sung-Ho Lee, Yongin-si (KR)

(73) Assignee: SAMSUNG SDI CO., LTD., Yongin-City (KR)

(21) Appl. No.: 13/802,195

(22) Filed: Mar. 13, 2013

(30) Foreign Application Priority Data
Apr. 23, 2012 (KR) 10-2012-0042012

(51) Int. Cl. C23C 16/448

(52) U.S. Cl. CPC C23C 16/4485
USPC 118/726

(57) ABSTRACT

A deposition apparatus includes a crucible having an inlet, a first heater heating the crucible, a tank supplying an object to be deposited to the crucible and having an outlet, a second heater heating the tank, and a transfer pipe connecting the outlet of the tank and the inlet of the crucible. The first heater has a first temperature range, and the second heater has a second temperature range lower than the first temperature range. The object to be deposited may be liquefied within the tank and transferred in the liquid state to the crucible via the transfer pipe. The amount of the object to be deposited within the crucible may be continuously maintained at an approximately constant value by regulation of the flow of the liquefied object to be deposited from the tank to the crucible based upon the weight of the object to be deposited within the crucible.

### CROSS-REFERENCE TO RELATED APPLICATIONS

This application claims priority to and the benefit of Korean Patent Application No. 10-2012-0042012, filed on Apr. 23, 2012, in the Korean Intellectual Property Office, the entire content of which is incorporated herein by reference.

### BACKGROUND

1. Field

Embodiments of the present disclosure relate to a deposition apparatus, and more particularly, to a deposition apparatus capable of continuously performing a deposition process for a long period of time.

2. Description of the Related Art

Apparatuses used for deposition are divided into an apparatus using heat and an apparatus using an electron beam. The apparatus using the heat uses a method of performing deposition by heating a source (e.g., the object to be deposited) using the heat. The apparatus using the electron beam uses a method of performing deposition by evaporating a source while converting electric energy transferred by an accelerated electron beam into thermal energy.

In the two methods described above, a deposition process is performed in the state in which a predetermined amount of source is contained in a container, such as a boat or crucible, that is a heating element. In this case, since the source in the container is reduced as the deposition process is performed, the reduction of the source may result in unequal deposition. Therefore, the source should be re-supplied to maintain the pre-determined amount in the container. For example, if the source is not re-supplied, the melting area of the source is decreased as the level of the source in the container is changed. Therefore, a change factor in the deposition process occurs, and the thickness and equality of a thin film deposited on the surface of an object to be deposited is influenced by the change factor. Accordingly, it is difficult to control the property of the thin film.

On the other hand, a general deposition apparatus has no component capable of constantly maintaining the amount of source. In addition, the roughly estimated amount of source is injected in to the container by an operator, or a supplementary amount of source is filled in the container by checking the amount of source remaining in the container during the deposition process. Therefore, it is difficult to obtain a uniform thickness of the thin film, and a problem of operator's safety may occur. Since the supply of the source is impossible during the deposition process, the source should be injected into the container after the deposition process is necessarily stopped so as to supply the source in the deposition apparatus.

### SUMMARY

Embodiments of the present disclosure provide a deposition apparatus capable of continuously performing a deposition process.

Embodiments of the present disclosure also provide a deposition apparatus having a miniaturized size and a new structure.

According to an embodiment of the present invention, there is provided a deposition apparatus including: a crucible having an inlet; a first heater heating the crucible; a tank supplying an object to be deposited to the crucible and having an outlet; a second heater heating the tank; and a transfer pipe connecting the outlet of the tank and the inlet of the crucible, where the first heater has a first temperature range, and the second heater has a second temperature range lower than the first temperature range.

The deposition apparatus may further include a chamber of which inside is in a vacuum state. The chamber may accommodate the crucible, the first heater, the tank and the second heater.

The deposition apparatus may further include a chamber of which inside is in a vacuum state. The chamber may accommodate the crucible and the first heater, and the tank may be provided to an outside of the chamber.

The chamber may further accommodate a plate, and a base material on which the object is deposited may be mounted on the plate.

The base material may include a positive or negative electrode plate used in a secondary battery. The object to be deposited may include lithium.

The base material may include a glass substrate, and the object to be deposited may include at least one of copper (Cu), indium (In), gallium (Ga) and selenium (Se).

The crucible may have a first surface including one or more openings, and the first surface may be provided to face the plate.

The plate may be provided above or below the crucible.

The object to be deposited may be liquefied in the tank and evaporated in the crucible.

The first temperature range may be greater than or equal to a boiling point of the object to be deposited, and the second temperature range may be a temperature range from about 95% of the melting point of the object to be deposited to about 105% of the melting point of the object to be deposited.

The crucible may be made of a stainless steel. In further embodiments, the crucible may be made of a molybdenum-bearing stainless steel grade (e.g., stainless steel grade 316, also referred to as SUS 316 or AISI 316). The first temperature range may be a temperature range from about the boiling point of the object to be deposited to about 1600 K (approximately 1327° C.).

The first and second heaters may include an insulating member provided to surround the first and second heaters at outer surfaces of the first and second heaters.

The outlet of the tank may be provided at a position higher than that of the inlet of the crucible.

A load cell measuring the weight of the object to be deposited, which is included in the crucible, may be provided to the crucible.

A valve may be provided to the transfer pipe.

The deposition apparatus may further include a controller connected to the load cell and the valve. The controller may receive the weight of the object to be deposited from the load cell and control opening/closing of the valve based upon the received weight.

In another embodiment, a deposition apparatus is provided. The deposition apparatus may comprise a crucible in thermal communication with a first heat source, a tank in thermal communication with a second heat source, and a conduit between the crucible and the tank. A deposition material may flow from the tank to the crucible, in a liquid state, via the conduit exits the crucible in a vapor state.

The first heat source may be capable of heating the crucible to a temperature greater than or equal to the boiling point of the deposition material and the second heat source is capable of heating the tank to a temperature within the temperature range between about 95% of the melting point of the deposition material and about 105% of the melting point of the deposition material.

The first heat source may be further capable of heating the crucible to a temperature within the temperature range from about the boiling point of the deposition material to about 1600 K.

In certain embodiments, the deposition material is urged to flow from the tank to the crucible by gravity alone.

The conduit may further comprise a valve which may adopt a position between a disengaged position and an engaged position. The deposition material flows uninhibited by the valve between the tank and the crucible via the conduit when the valve is in the open position and wherein at least a portion of the deposition material is inhibited by the valve from flow between the tank and the crucible via the conduit by a selected amount when the valve is in the engaged position.

The deposition apparatus may further comprise a control device that controls the position of the valve between the engaged and disengaged positions and a load measuring device that measures the weight of the deposition material held within the crucible in communication with the control device. The control device controls the position of the valve between the engaged and disengaged positions in response to the weight measured by the load measuring device to maintain the measured weight at approximately a selected value.

The crucible may include a plurality of openings facing a substrate for exit of deposition material in the vapor state from the crucible.

The deposition material may include lithium.

In a further embodiment, when the substrate is glass, the deposition material may include at least one of copper (Cu), indium (In), gallium (Ga) and selenium (Se).

As described above, according to embodiments of the present invention, it is possible to provide a deposition apparatus capable of continuously performing a deposition process.

Further, it is possible to provide a deposition apparatus having a miniaturized size and a new structure.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a perspective view of a deposition apparatus according to an embodiment of the present invention.

FIG. 2 is a schematic view of the deposition apparatus of FIG. 1.

FIG. 3 is a graph showing a change in temperature when an object to be deposited is lithium that is an embodiment of the present invention.

FIG. 4 is a schematic view of a deposition apparatus according to another embodiment of the present invention.

FIG. 5 is a schematic view of a deposition apparatus according to still another embodiment of the present invention.

FIG. 6 is a schematic view of a deposition apparatus according to still another embodiment of the present invention.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive.

In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements.

Hereinafter, exemplary embodiments of the present invention will be described with reference to the accompanying drawings.

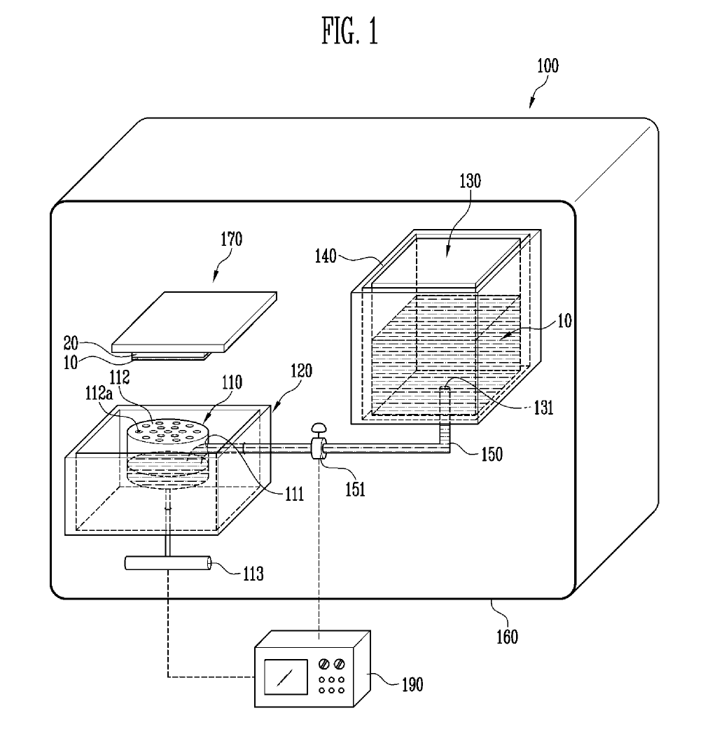

FIG. 1 is a perspective view of a deposition apparatus according to an embodiment of the present invention. FIG. 2 is a schematic view of the deposition apparatus of FIG. 1.

Referring to FIGS. 1 and 2, the deposition apparatus 100 may include a crucible 110 having an inlet 111; a first heater 120 heating the crucible 110; a tank 130 supplying an object 10 to be deposited to the crucible 110 and having an outlet 131; a second heater 140 heating the tank 130; and a transfer pipe 150 connecting the outlet 131 of the tank 130 and the inlet 111 of the crucible 110. Here, the first heater 120 may have a first temperature range and the second heater 140 may have a second temperature range lower than the first temperature range. The deposition apparatus 100 may further include a chamber 160 of which inside is in a vacuum state, and the chamber 160 may accommodate the crucible 110, the first heater 120, the tank 130 and the second heater 120. The object 10 to be deposited may also be interchangeably referred to herein as a deposition material. It may be further understood by one of ordinary skill in the art that, the material being deposited upon a base material (e.g., a substrate) may include one or more materials, without limit.

The chamber 160 accommodates the crucible 110 and the tank 130 as a space in which a deposition process is performed, and the inside of the chamber 160 is provided to be in a vacuum state. The deposition process is performed at a high temperature as a process of evaporating a substance and depositing the evaporated substance on a base material (e.g., a substrate). This vacuum state is maintained because, when air or the like is flowed in the inside of the chamber 160, the air is evaporated in the chamber 160 so as to be deposited on the base material, which causes a defect of the base material.

The chamber 160 may further include a mounting plate 170, and a base material on which the object 10 is to be deposited may be mounted on the mounting plate 170. The mounting plate 170 allows the base material to be placed at a correct position while the deposition process is performed, thereby facilitating the deposition process. For example, the base material may include a positive or negative electrode plate, and the object 10 to be deposited may include a material for pre-charging the base material. Preferably, the object 10 to be deposited includes lithium. The base material may include a glass substrate. In this case, the base material may include at least one of copper (Cu), indium (In), gallium (Ga), and selenium (Se).

The crucible 110 may have the inlet 111 through which the object 10 to be deposited is flowed in the inside of the crucible 110. The crucible 110 may include a first surface 112 having an opening 112a, and the first surface 112 may be provided to face the mounting plate 170. For example, the mounting plate 170 may be provided above the crucible 110. The first heater 120 heating the crucible 110 may be provided adjacent to the crucible 110 (e.g., around at least a portion of the crucible 110). The first heater 120 may have the first temperature range.

The object 10 to be deposited may be provided in the inside of the crucible 110. In this case, the object 10 to be deposited is evaporated by the first heater 120 so as to be deposited on the base material provided to the mounting plate 170. The first surface 112 of the crucible 110 may have one or more openings 112a, and the object 10 to be deposited, which is evaporated through the openings 112a, may be exhausted to the outside of the crucible 110 in a vapor state so as impinge upon the base material and cool to the solid state, resulting in the object 10 being deposited on the base material. In this case, the amount or position of the object 10 to be deposited, which is mounted on the base material, may be controlled by adjusting the size or number of the openings 112a. The first heater 120 may have the first temperature range, e.g., a temperature range corresponding to about the boiling point of the object 10 to be deposited.

A load cell 113 measuring the weight of the object 10 to be deposited, which is included in the crucible 110, may be provided in the crucible 110. The load cell 113 may measure the weight of the object 10 to be deposited, which is evaporated and decreased in the crucible 110, i.e., the amount of the evaporated object 10 to be deposited.

The tank 130 is a portion of the deposition apparatus 100 that supplies or keeps the object 10 to be deposited, and the outlet 131 may be provided to the tank 130. The outlet 131 of the tank 130 may be connected to the inlet 111 of the crucible 110 by the transfer pipe 150, and the object 10 to be deposited, which is flowed out through the outlet 131 of the tank 130, is supplied to the inside of the crucible 110 through the inlet 111 of the crucible 110. The transfer pipe 150 may be provided with a valve 151, and the valve 151 may control the flow rate of the object 10 to be deposited from the tank 130 to the crucible 110.

The second heater 140 may heat the object 10 to be deposited and may be provided in the inside of the tank 130. The object 10 so heated may be further provided to the tank 130. The second heater 140 is extended to surround at least a portion of the transfer pipe 150. Thus, the second heater 140 can heat the object 10 to be deposited, which passes through the transfer pipe 150. The second heater 140 may have the second temperature range, and the second temperature range may be a temperature range lower than the first temperature range of the first heater 120. For example, the second temperature range may be a temperature range corresponding to the melting point of the object 10 to be deposited.

Generally, when an object in the vapor phase is deposited on a base material by heating a crucible containing the object to be deposited and evaporating the object to be deposited or when the object is deposited on a large quantity of base materials or deposited for a long period of time, a large amount of the object to be deposited is required, and therefore, a problem is caused in a deposition process. Conventionally, these problems have been addressed by employing either a first method in which a large amount of the object to be deposited is provided once or a second method in which the object to be deposited is provided throughout several times. However, both of these methods are problematic.

First, in the first method, as the amount of the object to be deposited increases, the scale of a crucible, chamber, heater or the like increases. Therefore, the installation space of the chamber is restricted, and the manufacturing cost of a deposition apparatus is increased. In a deposition process, as the size of the crucible increases, it is difficult to control evaporation conditions of the object to be deposited. Therefore, this results in the unequal deposition thickness and quality failure of the base material on which the object is deposited. As the object to be deposited is evaporated, the amount of the object to be deposited is decreased, and therefore, the decrease in the amount of the object to be deposited has influence on the amount of the evaporated object.

The second method is a method in which the object to be deposited is provided in the crucible throughout several times, and accordingly, a problem of spatial restriction and manufacturing cost can be solved by the first method. On the other hand, a separate inlet is necessarily provided to the crucible so as to re-supply the object to be deposited to the crucible. Since the object to be deposited may be flowed out through the inlet provided to the crucible, it is difficult to control the amount of the object to be deposited on the base material. Although the inlet is blocked by a cover, the object is deposited in a gap of the cover, and therefore, the crucible may be contaminated. In order to re-supply the object to be deposited, the chamber is necessarily opened by releasing the vacuum of the chamber. In this case, the inside of the chamber is contaminated due to the flow of air in the opened chamber, and therefore, this may have influence on the deposition of the object. Since the large-sized chamber is necessarily maintained again in the vacuum state, much time is consumed, thereby lowering process efficiency.

According to the present invention, there is provided a deposition apparatus capable of performing a deposition process continuously performed, even in the chamber under a vacuum atmosphere, and improving the deposition thickness and physical property of the base material by controlling the object to be deposited, which is evaporated in the inside of the chamber. Further, there is provided a deposition apparatus capable of continuously depositing an object to be deposited on a large quantity of base materials through the one-time supply of the object, without providing a large amount of the object once or providing the object throughout several times, and performing a deposition process for a long period of time.

In the deposition apparatus 100, the outlet 131 of the tank 130 may be provided at a position higher than that of the inlet 111 of the crucible 110. Therefore, in the chamber 160, the tank 130 may be provided at a position relatively higher than that of the crucible 110. The deposition apparatus 100 may further include a control device (e.g., controller 190) connected to the load cell 113 and the valve 151. The control unit 190 may receive measurements of the weight of the object 10 to be deposited from the load cell 113 and control the opening/closing of the valve 151. In this manner, the amount of the object 10 to be deposited that is within the crucible 110 may be held approximately constant. For example, the amount of the object 10 to be deposited that is within the crucible 110 may be held within about 20% or less of a selected amount (e.g., within about 15% or less of the selected amount, within about 10% or less of the selected amount, within about 5% or less of a selected amount, within about 1% or less of the selected amount, within about 0.1% or less of the selected amount, etc.).

First, the object 10 to be deposited in a solid state is filled in the inside of the tank 130, and subsequently, the inside of the chamber 160 is maintained in a vacuum state. Although not shown in these figures, the chamber 160 may be provided with, for example, a vacuum pump or the like. Subsequently, the tank 130 is heated using the second heater 140, and the object 10 to be deposited is phase-changed from solid to liquid. In this case, the outlet 131 of the tank 130 is provided at the position higher than that of the inlet 111 of the crucible 110, and thus the liquefied object 10 to be deposited is flowed in the crucible 110 through the transfer pipe 150 by gravity. That is to say, in certain embodiments, the liquefied object 10 to be deposited may be transported from the tank 130 to the crucible 110 only under the influence of gravity, without using a separate source of energy for transport (e.g., a mechanical pump, etc.).

Subsequently, the liquefied object 10 to be deposited, which is flowed in the crucible 110 through the inlet 111 of the crucible 110, is evaporated by heating the crucible 110 using the first heater 120. The evaporated object 10 to be deposited is exhausted to the outside through the openings 112a provided in the first surface 112 of the crucible 110, thereby performing the deposition process. In order to constantly maintain the amount of the evaporated object 10 to be deposited in the chamber 160, it is necessary to constantly maintain the amount of the object 10 to be deposited in the crucible 110 during the deposition process. Thus, the load cell 113 detects a change in the weight of the object 10 to be deposited in the crucible 110 and transmits the detected change to the controller 190. The controller 190 enables the amount of the object 10 to be deposited in the crucible 110 to be constantly maintained by controlling opening/closing of the valve 151 provided to the transfer pipe 150 according to the change in the weight of the object 10 to be deposited, which is transferred from the load cell 113.

The deposition apparatus 100 according to this embodiment can constantly maintain the total amount of the object 10 to be deposited in the crucible 110, and thus the amount the evaporated object 10 to be deposited in the chamber 160 can be constantly maintained at about the same amount. Accordingly, it is possible to obtain constant deposition quality. The object 10 to be deposited is phase-changed into a liquid state in the tank 130 before being supplied to the crucible 110. Therefore, the object 10 to be deposited is phase-changed from the liquid state to a gas state when undergoing further heating in the crucible 110, unlike conventional deposition system where the object to be deposited is conventionally phase-changed from a solid state to the gas state (via the liquid state) in a crucible. Thus, a degree of the phase-change of the object 10 to be deposited is relatively small in the deposition process, and the heating of the crucible 10 can be easily controlled. Accordingly, it is possible to maintain constant deposition quality including the thickness and density of the object 10 to be deposited on the base material, and the like.

As described above, the object 10 to be deposited may liquefied in the tank 130 and evaporated in the crucible 110. Therefore, the second temperature range of the second heater 140 heating the tank 130 may be set lower than the first temperature range of the first heater 120 heating the crucible 110. For example, the first temperature range may be about the boiling point or higher of the object 10, and the second temperature range may be a temperature range of about 95% of the melting point of the object 10 to the temperature point at which the object 10 is not evaporated. Preferably, the second temperature range is a temperature range from about 95% of the melting point of the object 10 to about 105% of the melting point of the object 10.

If the first temperature range were less than the boiling point of the object, the object 10 to be deposited would not be evaporated, and therefore, the deposition process may not be performed. Furthermore, if the second temperature were less than 95% of the melting point of the object, it would be difficult to liquefy the object 10 to be deposited, or the liquidity of the object 10 to be deposited is lowered. Therefore, the contamination of the deposition apparatus is caused. In addition, the object 10 to be deposited is not smoothly flowed, and therefore, it is difficult to continuously perform the deposition process. On the other hand, when the second temperature range exceeds about 105% of the melting point of the object 10, a portion of the object 10 to be deposited is evaporated, or unnecessary energy consumption is caused.

For example, the crucible 110 may be made of SUS 316, and the first temperature range may be a temperature range from the boiling point of the object 10 to about 1600 K. The melting point of the SUS 316 may be within the range between about 1640 K (e.g., about 1643.15 K) to about 1675 K (e.g., about 1673.15 K). If the object 10 to be deposited were heated up to the melting point or higher of the crucible 110 made of the SUS 316, a structure material of the crucible 110 may be melted out. Since the structure material of the crucible 110 would then be mixed with the object 10 to be deposited, the quality of the object 10 to be deposited would be deteriorated, and the property of the object 10 to be deposited would be changed. Therefore, when the crucible 110 made of the SUS 316 is used, the first temperature range may be a temperature range from about the boiling point of the object to be deposited (e.g., less than the melting temperature of the crucible) to about 1600 K or lower.

Since only the object 10 to be deposited is liquefied in the tank 130, the object 10 to be deposited is not in the gas state when held within the tank 130. Thus, the liquefied object 10 to be deposited is not absorbed in a joint of the tank 130, and hence the inside of the tank 130 is not contaminated. Accordingly, when an inlet through which the object 10 to be deposited is injected into the tank 130 is provided to the tank 130, the shape and size of the inlet are not restricted, and hence the tank inlet can be provided in various shapes. In addition, since the size of the tank inlet can be formed sufficiently large, powder or bar-type object can be used as the object 10 to be deposited, and the tank inlet is not influenced by the shape of the object 10 to be deposited.

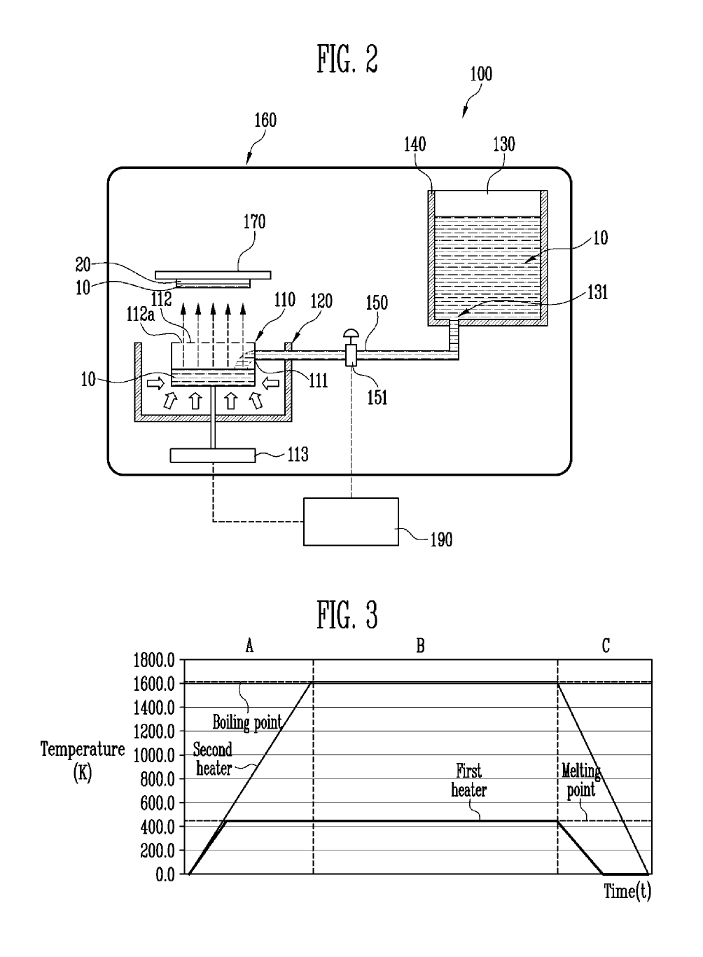

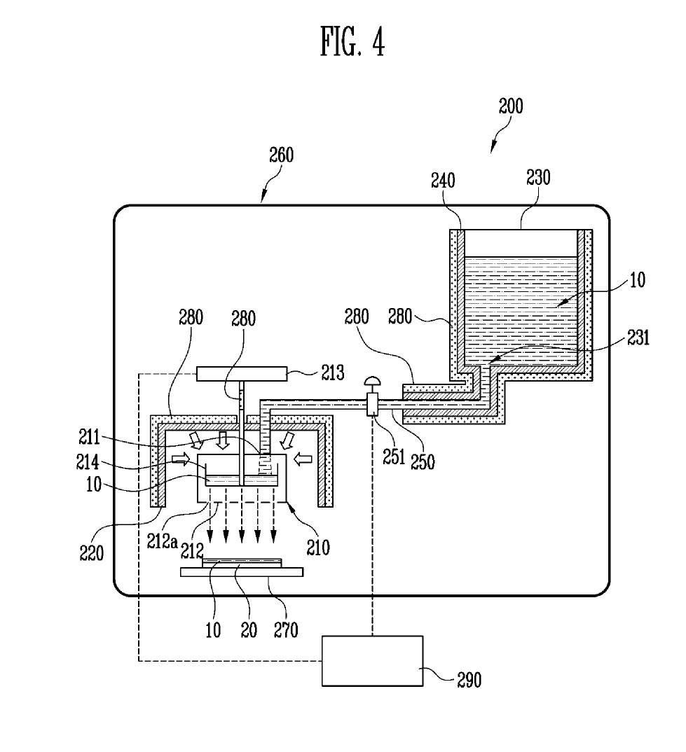

FIG. 3 is a graph showing a change in temperature when an object to be deposited is lithium that is an embodiment of the present invention.

Referring to FIG. 3, the boiling point of the lithium may be about 1615 K and the melting point of the lithium may be about 453.69 K. The deposition apparatus 100 according to this embodiment may be used to pre-charge a positive or negative electrode plate (hereinafter, referred to as an electrode plate) used in a secondary battery. In this case, the electrode plate is provided in the chamber using a winding roll. The electrode plate unwound from the winding roll is mounted on the mounting plate 170 so that the deposition process is performed, and the deposited electrode plate is rewound around the winding roll. The electrode plate passes through the mounting plate 170 while being consecutively unwound and rewound by the winding roll. Thus, the lithium is deposited on the electrode plate and then pre-charged.

Since a metal, particularly the lithium, has adhesion in a solid state, the metal may be adhered to the inside of the tank 130 or the transfer pipe 150. When the lithium in the solid state is deposited by being directly heated, the internal phase change of the lithium instantaneously occurs, and therefore, the amount of the evaporated lithium is changed. Accordingly, it is difficult to obtain constant deposition quality. On the other hand, in the deposition apparatus 100 according to embodiments of the present invention, the lithium having adhesion in the solid state does not contaminate the deposition apparatus 100. Thus, the deposition apparatus 100 can be used for a long period of time, and is not influenced by the form of a raw material of the original lithium. Further, the deposition process can be continuously performed for a long period of time without re-supplying the lithium to the deposition apparatus 100.

With continued reference to FIG. 3, the temperature of the lithium is gradually increased by the second heater 140 as shown in area A of FIG. 3, and thus the lithium is liquefied. Then, the temperature of the lithium is kept constant for a selected period of time (i.e., area B of FIG. 3) by the first heater 120, and thus the liquefied lithium is evaporated. The lithium exhausted from the crucible 110 is deposited, and thus the temperature of the lithium is changed, as shown in area C of FIG. 3. Therefore, the second temperature range of the second heater 140 may correspond to the melting point of the lithium that is the object to be deposited, and the first temperature range of the first heater 120 may correspond to the boiling point of the lithium that is the object to be deposited. In this case, the first temperature range may have a temperature range higher than the boiling point of the lithium so as to increase the deposition speed of the evaporated object to be deposited. Although it has been described in this embodiment that the electrode plate is provided using the winding roll, the present invention is not limited thereto. That is, the electrode plate may be variously modified, including a base material formed in a substrate shape.

Hereinafter, other embodiments of the present invention will be described with reference to FIGS. 4 to 6. Contents of these embodiments, except the following contents, are similar to those of the embodiment described with reference to FIGS. 1 to 3, and therefore, their detailed descriptions will be omitted.

FIG. 4 is a schematic view of a deposition apparatus 200 according to another embodiment of the present invention.

Referring to FIG. 4, the deposition apparatus 200 according to this embodiment may include a crucible 210 having an inlet 211, a first heater 220, a tank 230 having an outlet 231, a second heater 240, and a transfer pipe 250 connecting the outlet 231 of the tank 230 and the inlet 211 of the crucible 210. Here, the first heater 220 may have a first temperature range and the second heater 240 may have a second temperature range lower than the first temperature range.

The crucible 210, the first heater 220, the tank 230 and the second heater 240 may be accommodated in a chamber 260 of which inside is in a vacuum state. A load cell 213 measuring the weight of an object 10 to be deposited in the crucible 210 may be provided to the crucible 210, and a valve 251 may be provided to the transfer pipe 250. A controller 290 may control the opening/closing of the valve 251 based on data transferred from the load cell 213. Thus, the controller 290 enables the total amount of the object 10 to be deposited in the crucible 210 to be constantly maintained.

A plate 270 may be provided in the chamber 260. In contrast to the deposition apparatus 100 of FIGS. 1 and 2, where the plate 170 was provided above the crucible 110, in the embodiment of FIG. 4, the plate 270 may be provided below the crucible 210. The crucible 210 may be provided with a container 214 accommodating the object 10 to be deposited in the inside thereof

The crucible 210 includes a first surface 212 having one or more openings 212a, and the first surface 212 is provided to face the plate 270. Thus, the first surface 212 faces a bottom surface of the chamber 260, and the object 10 to be deposited, which is flowed in the crucible 210 through the inlet 211 of the crucible 210 can be accommodated in the container 214. The object 10 to be deposited, which is evaporated in the container 214, may be exhausted through the openings 212a of the first surface 212 so as to be deposited on a base material mounted on the plate 270.

The first and second heaters 220 and 240 may include an insulating member 280 provided to surround the first and second heaters 220 and 240 at outer surfaces of the first and second heaters 220 and 240. The insulating member 280 is provided to prevent thermal conduction between the crucible 210 and the tank 230, respectively heated by the first and second heaters 220 and 240. The insulating member 280 may be provided to surround at least a portion of the second heater 240 may be further extended to surround the transfer pipe 250.

In the deposition apparatus 200 according to this embodiment, the first and second heaters 220 and 240 may have first and second temperature ranges different from each other. Since the first and second temperature ranges are high temperature ranges, the first and second temperature ranges may be transferred around the first and second heaters 220 and 240 by thermal conduction. If the insulating member 280 is not used, heat loss occurs, and therefore, unnecessary energy consumption may be caused.

For example, when the temperature is transferred to the transfer pipe 250 or the tank 230 by the second heater 220, the object 10 to be deposited, which is provided in the inside of the tank 230, is evaporated, and therefore, unnecessary contamination of the deposition apparatus may be caused. Since relative heat loss occurs in the second heater 240, additional energy for compensating for the heat loss may be consumed so as to heat the crucible 210. Accordingly, when the first and second heaters 220 and 240 has different temperature ranges, the insulating member 280 is provided to the first and second heaters 220 and 240, and thus energy can be efficiently used. The insulating member 280 is provided between the crucible 210 and the load cell 213, so that the heat applied to the crucible 210 cannot be transferred to the load cell 213.

FIG. 5 is a schematic view of a deposition apparatus 300 according to still another embodiment of the present invention.

Referring to FIG. 5, the deposition apparatus 300 according to this embodiment may include a crucible 310, a first heater 320 heating the crucible 310, a tank 330, a second heater 340 heating the tank 330, and a transfer pipe 350 connecting the tank 330 and the crucible 310. Here, the first heater 320 may have a first temperature range and the second heater 340 may have a second temperature range lower than the first temperature range.

The deposition apparatus 300 may further include a chamber 360 of which inside is in a vacuum state. The chamber 360 may accommodate the crucible 310 and the first heater 320, and the tank 330 may be provided to the outside of the chamber 360. In this case, the tank 330 may have a vacuum pump 335, so that the inside of the tank 330 can be maintained in the vacuum state.

In the deposition apparatus 300 according to this embodiment, the tank 330 keeping the object 10 to be deposited and supplying the object 10 to the crucible 310 is provided to the outside of the chamber 360. Thus, the size of the chamber 360 can be minimized. Since the separate vacuum pump 335 is provided to the tank 330, the vacuum state of the chamber 360 can be maintained in the state in which a valve 351 of the transfer pipe 350 is opened. When the tank 330 is provided to the outside of the chamber 360 as described above, the object 10 to be deposited can be supplied into the tank 330 in the state in which the valve 351 of the transfer pipe 350.

That is, since the object 10 to be deposited is supplied into the tank 330 in real time, the size of the second heater 340 can be minimized. Since the tank 330 can supply the object 10 to be deposited to the crucible in real time, the size of the first heater 320 can also be minimized. In this case, a controller 390 may receive the total amount of the object 10 to be deposited from the load cell 313 and control the valve 351 of the transfer pipe 350, so that the amount of the object 10 to be deposited in the crucible 310 can be constantly maintained. Thus, the size of the chamber 360 accommodating the crucible 310 and the first heater 320 can be minimized, thereby reducing manufacturing cost and operating cost.

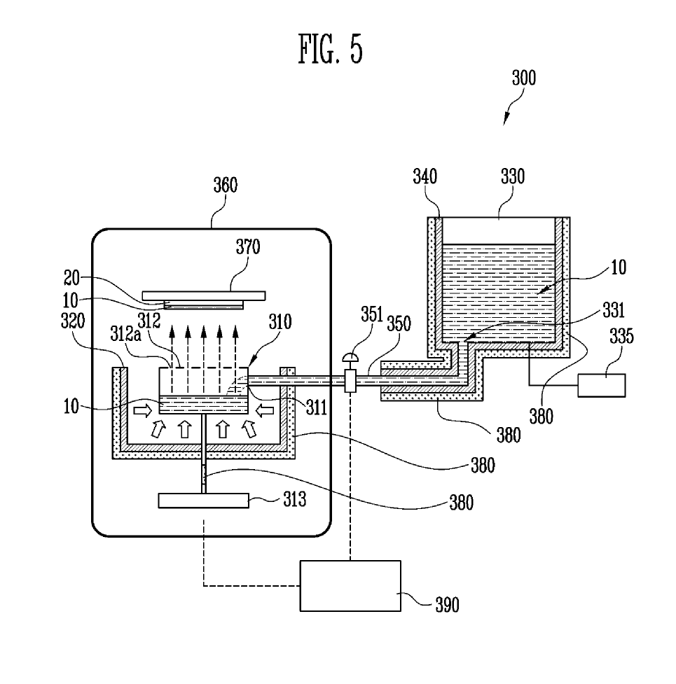

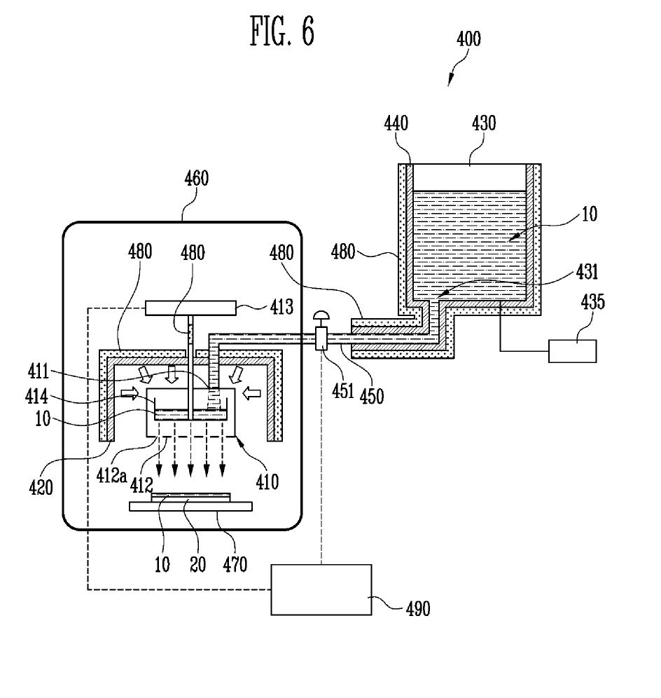

FIG. 6 is a schematic view of a deposition apparatus 400 according to still another embodiment of the present invention.

Referring to FIG. 6, the deposition apparatus 400 according to this embodiment include a chamber 460 accommodating a crucible 410 and a first heater 420, and a tank 430 and a second heater 440, which are provided to the outside of the chamber 460. The tank 430 and the crucible 410 may be connected by a transfer pipe 450. A controller 490 may maintain the total amount of an object to be deposited in the crucible 410 to be constant by receiving data transmitted from a load cell 414 connected to the crucible 410 and controlling a valve 451 of the transfer pipe 450. The first heater 420 may has a first temperature range and the second heater 440 may have a second temperature range lower than the first temperature range.

The deposition apparatus 400 according to this embodiment may perform a downward deposition process. In this case, in contrast to the deposition apparatus 300, where the plate 370 was provided above the crucible 310, a plate 470 provided in the chamber 460 may be provided below the crucible 410. A container 414 may be provided in the crucible 410, and an object 10 to be deposited in the container 414 is evaporated and exhausted through one or more openings 412a of the first surface 412 of the crucible 410. Then, the evaporated object 10 to be deposited may be deposited on a base material mounted on the plate 470. The tank 430 may be provided with a vacuum pump 435 so as to maintain a vacuum state of the tank 430.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof

What is claimed is:

1. A deposition apparatus comprising:
a crucible having an inlet;
a first heater heating the crucible;
a tank supplying an object to be deposited to the crucible and having an outlet;
a second heater heating the tank; and
a transfer pipe connecting the outlet of the tank and the inlet of the crucible,
wherein the first heater has a first temperature range, and the second heater has a second temperature range lower than the first temperature range.

2. The deposition apparatus according to claim 1, further comprising a chamber of which inside is in a vacuum state, wherein the chamber accommodates the crucible, the first heater, the tank and the second heater.

3. The deposition apparatus according to claim 1, further comprising a chamber of which inside is in a vacuum state, wherein the chamber accommodates the crucible and the first heater, and the tank is provided to an outside of the chamber.

4. The deposition apparatus according to claim 2, wherein the chamber further accommodates a plate, and a base material on which the object is deposited is mounted on the plate.

5. The deposition apparatus according to claim 4, wherein the base material includes a positive or negative electrode plate used in a secondary battery.

6. The deposition apparatus according to claim 1, wherein the object to be deposited includes lithium.

7. The deposition apparatus according to claim 4, wherein the base material includes a glass substrate, and the object to be deposited includes at least one of copper (Cu), indium (In), gallium (Ga) and selenium (Se).

8. The deposition apparatus according to claim 4, wherein the crucible has a first surface including one or more openings, and the first surface is provided to face the plate.

9. The deposition apparatus according to claim 8, wherein the plate is provided above or below the crucible.

10. The deposition apparatus according to claim 1, wherein the object to be deposited is liquefied in the tank and evaporated in the crucible.

11. The deposition apparatus according to claim 1, wherein the first temperature range is greater than or equal to the boiling point of the object to be deposited, and the second temperature range is a temperature range from about 95% of the melting point of the object to be deposited to about 105% of the melting point of the object to be deposited.

12. The deposition apparatus according to claim 11, wherein the crucible is made of SUS 316, and the first temperature range is a temperature range from about the boiling point of the object to be deposited to about 1600 K.

13. The deposition apparatus according to claim 1, wherein the first and second heaters include an insulating member provided to surround the first and second heaters at outer surfaces of the first and second heaters.

14. The deposition apparatus according to claim 1, wherein the outlet of the tank is provided at a position higher than that of the inlet of the crucible.

15. The deposition apparatus according to claim 1, wherein a load cell measuring the weight of the object to be deposited, which is included in the crucible, is provided to the crucible.

16. The deposition apparatus according to claim 15, wherein a valve is provided to the transfer pipe.

17. The deposition apparatus according to claim 1, further comprising a controller connected to the load cell and the valve, wherein the controller receives the weight of the object to be deposited from the load cell and controls opening/closing of the valve based upon the received weight.

18. The deposition apparatus according to claim 3, wherein the chamber further accommodates a plate, and a base material on which the object is deposited is mounted on the plate.

19. A deposition apparatus, comprising:
a crucible in thermal communication with a first heat source;
a tank in thermal communication with a second heat source; and
a conduit between the crucible and the tank;
wherein a deposition material flows from the tank to the crucible, in a liquid state, via the conduit; and
wherein the deposition material exits the crucible in a vapor state.

20. The deposition apparatus of claim 19, wherein the first heat source is capable of heating the crucible to a temperature greater than or equal to the boiling point of the deposition material and wherein the second heat source is capable of heating the tank to a temperature within the temperature range between about 95% of the melting point of the deposition material and about 105% of the melting point of the deposition material.
